(19) United States
(12) Patent Application Publication
(10) Pub. No.: US 2026/0090390 A1
(43) Pub. Date: Mar. 26, 2026

(54) ELECTROMAGNETIC WAVE SHIELDING SHEET, SHIELDED WAFER, SEMICONDUCTOR DEVICE AND MANUFACTURING METHOD THEREOF

(71) Applicants: artience Co., Ltd., Tokyo (JP); TOYOCHEM CO., LTD., Tokyo (JP)

(72) Inventors: Kenji ANDO, Tokyo (JP); Kazunori MATSUDO, Tokyo (JP); Tamaki MATSUO, Tokyo (JP)

(73) Assignees: artience Co., Ltd., Tokyo (JP); TOYOCHEM CO., LTD., Tokyo (JP)

(21) Appl. No.: 19/306,996

(22) Filed: Aug. 21, 2025

(30) Foreign Application Priority Data
Sep. 20, 2024 (JP) 2024-164422

(51) Int. Cl. H01L 23/552; H01L 21/50; H01L 21/78

(52) U.S. Cl. CPC H10W 42/20; H10W 95/00; H10P 54/00

(57) ABSTRACT

Provided are a highly reliable electromagnetic wave shielding sheet that is capable of performing batch coating on a wafer before dicing and has excellent coating properties, a shielded wafer formed using the electromagnetic wave shielding sheet, a semiconductor device, and a manufacturing method thereof. An electromagnetic wave shielding sheet 3 for performing batch coating on a semiconductor wafer before dicing includes at least a shielding film 30 including a conductive filler (F) and a binder component, has an elongation rate of 100% to 1500% at 100° C., and has a Young's modulus of 100 MPa to 1000 MPa at 100° C. in a cured sheet after treating the electromagnetic wave shielding sheet 3 at 180° C. for 2 hours.

### INCORPORATION BY REFERENCE

This application is based upon and claims the benefit of priority from Japanese patent application No. 2024-164422, filed on Sep. 20, 2024, the disclosure of which is incorporated herein in its entirety by reference.

### BACKGROUND

The disclosure relates to an electromagnetic wave shielding sheet, a shielded wafer, a semiconductor device, and a manufacturing method thereof.

In order to prevent the semiconductor components integrated inside electronic devices such as mobile terminals from malfunctioning, technology is required for shielding electromagnetic noise generated from the semiconductor components and electromagnetic noise from outside.

International Publication No. 2019/117259 discloses a manufacturing method of a mounting structure, including a step of preparing a mounting member on which multiple second circuit members are mounted on a first circuit member, a step of forming a first cured layer covering this mounting member, and a step of forming a functional layer such as a shield cover layer on the first cured layer by a vapor phase method and/or a plating method. Besides, Japanese Patent Application Laid-Open No. 2016-092275 discloses a sealing material with an electromagnetic wave shielding support substrate that includes a support substrate having electromagnetic wave shielding properties, and a sealing material laminated on this support substrate.

### SUMMARY

In response to the trend toward lighter, thinner, shorter, and smaller electronic devices, high-density mounting that realizes miniaturization and weight reduction is also required for semiconductor packages. For this reason, wafer level chip size package (WL-CSP) technology is attracting attention, which packages semiconductor elements formed on a wafer by forming external terminals and sealing resin at the stage before dicing the wafer without performing internal wiring by bonding wires. If it is possible to provide an electromagnetic wave shielding sheet that can perform batch coating on such a wafer and can also cover the sides of semiconductor devices after dicing, there would be significant advantages in terms of versatility, economy, and mass productivity.

The disclosure has been made in view of the above background, and aims to provide a highly reliable electromagnetic wave shielding sheet that is capable of performing batch coating on a semiconductor wafer before dicing and has excellent coating properties, a shielded wafer formed using the electromagnetic wave shielding sheet, a semiconductor device, and a manufacturing method thereof.

As a result of intensive studies, the inventors found that the problem of the disclosure can be solved in the following aspects, leading to the completion of the disclosure.

[1]: An electromagnetic wave shielding sheet, for performing batch coating on at least one main surface of a semiconductor wafer before dicing which includes half-cut grooves formed in a lattice pattern and element formation regions partitioned by the half-cut grooves and arranged in a matrix pattern,
the electromagnetic wave shielding sheet including at least a shielding film that includes a binder component and a conductive filler (F),
in which an elongation rate at 100° C. of the electromagnetic wave shielding sheet is 100% to 1500%, and
a Young's modulus at 100° C. of a cured sheet after treating the electromagnetic wave shielding sheet at 180° C. for 2 hours is 100 MPa to 1000 MPa.

[2]: The electromagnetic wave shielding sheet according to [1], in which a peeling rate in an adhesion test after performing a pressure cooker test based on JIS K5600-5-6 on a shield cover layer derived from the electromagnetic wave shielding sheet after thermocompression bonding the electromagnetic wave shielding sheet to an entire main surface of a silicon bare wafer at 120° C. and 5 MPa for 3 minutes, followed by treatment at 180° C. for 2 hours, is less than 15%.

[3]: The electromagnetic wave shielding sheet according to [1] or [2], in which the binder component includes a curable compound (C) having a weight average molecular weight of 5,000 or less, and a high molecular weight resin (P) having a weight average molecular weight of 10,000 or more.

[4]: The electromagnetic wave shielding sheet according to any one of [1] to [3], in which a content ratio of the conductive filler (F) is 45% by mass to 85% by mass.

[5]: The electromagnetic wave shielding sheet according to any one of [1] to [4], in which a product of an average specific surface area [m²/g] of the conductive filler (F) and a content [g] of the conductive filler (F) relative to 100 parts by mass of the binder component is 50 to 1200 [m²].

[6]: The electromagnetic wave shielding sheet according to any one of [1] to [5], in which the curable compound (C) includes an epoxy group-containing compound (E) having a weight average molecular weight of 5,000 or less, an epoxy equivalent of the epoxy group-containing compound (E) is 110 g/eq to 1000 g/eq, and 10 parts by mass to 80 parts by mass of the epoxy group-containing compound (E) is included relative to 100 parts by mass of the high molecular weight resin (P).

[7]: The electromagnetic wave shielding sheet according to any one of [1] to [6], in which a shield cover layer derived from the electromagnetic wave shielding sheet is formed after thermocompression bonding the electromagnetic wave shielding sheet at 120° C. and 5 MPa for 3 minutes to an entire main surface of a 12-inch silicon bare wafer having half-cut grooves with a width of 200 μm and a depth of 200 μm formed in a lattice pattern at intervals of 4000 μm, and treating at 180° C. for 2 hours, and a resistance value between the shield cover layers coated on convex portions at adjacent positions via the half-cut grooves is 5 mΩ to 300 mΩ.

[8]: A shielded wafer, including a shield cover layer formed by the electromagnetic wave shielding sheet according to any one of [1] to [7] on at least one main surface of a semiconductor wafer before dicing.

[9]: A semiconductor device, in which the shielded wafer according to [8] is diced in units of element formation regions.

[10]: A manufacturing method of a semiconductor device, including:
a step of forming half-cut grooves in a semiconductor wafer before dicing which includes element formation regions formed in a matrix pattern along scribe lines;
a step of disposing the electromagnetic wave shielding sheet according to any one of [1] to [7] above the semiconductor wafer;
a step of thermocompression bonding the electromagnetic wave shielding sheet to the semiconductor wafer;
a step of obtaining a shield cover layer by heating and curing the electromagnetic wave shielding sheet; and
a step of dicing in units of the element formation regions.

The disclosure achieves excellent effects in providing a highly reliable electromagnetic wave shielding sheet that is capable of performing batch coating on a semiconductor wafer before dicing and has excellent coating properties, a shielded wafer formed using the electromagnetic wave shielding sheet, a semiconductor device, and a manufacturing method thereof.

The above and other objects, features and advantages of the present disclosure will become more fully understood from the detailed description given hereinbelow and the accompanying drawings.

### BRIEF DESCRIPTION OF DRAWINGS

FIG. 1 is a schematic explanatory view showing an example of the wafer according to an embodiment.

FIG. 2 is a cross-sectional view taken along line II-II of FIG. 1.

FIG. 3 is a partially enlarged view of FIG. 2.

FIG. 4 is a schematic cross-sectional view showing an example of the wafer with shield processing according to Modification Example 1.

FIG. 5 is a schematic cross-sectional view showing an example of the wafer with shield processing according to Modification Example 2.

FIG. 6 is a schematic cross-sectional view showing an example of the wafer with shield processing according to Modification Example 3.

FIG. 7 is a side view showing an example of the electromagnetic wave shielding sheet according to an embodiment.

FIG. 8 is a side view showing an example of the electromagnetic wave shielding sheet according to a modification example.

FIG. 9 is a schematic cross-sectional view showing an example of main parts of the semiconductor device according to an embodiment.

FIG. 10 is a schematic cross-sectional view showing an example of main parts of the semiconductor device according to a modification example.

FIG. 11 is a schematic explanatory view showing an example of a manufacturing process of the semiconductor device according to an embodiment.

FIG. 12 is a schematic explanatory view showing an example of a manufacturing process of the semiconductor device according to an embodiment.

FIG. 13 is a schematic explanatory view showing an example of a manufacturing process of the semiconductor device according to an embodiment.

FIG. 14 is a schematic explanatory view showing an example of a manufacturing process of the semiconductor device according to an embodiment.

FIG. 15 is a schematic explanatory view showing an example of a manufacturing process of the semiconductor device according to an embodiment.

### DESCRIPTION OF EMBODIMENTS

Hereinafter, the disclosure will be described in detail. Other embodiments are also included in the scope of the disclosure as long as they conform to the spirit of the disclosure. In this specification, numerical ranges specified using “to” include values described before and after the numerical values. Various components in this specification may each independently be used alone or in combination of two or more types unless otherwise noted. The numerical values described in this specification refer to values obtained by methods described in [Examples], etc. described later.

### 1. Shielded Wafer

The shielded wafer of the disclosure is a wafer having a shield cover layer (hereinafter also referred to as SC layer) formed by covering at least one main surface of a semiconductor wafer before dicing with the electromagnetic wave shielding sheet (hereinafter also referred to as ES sheet) of the disclosure. The ES sheet is a sheet for performing batch coating on the semiconductor wafer (hereinafter also simply referred to as wafer), and has at least a shielding film including a binder component and a conductive filler (F). In this specification, the conductive filler (F) (hereinafter also simply referred to as filler (F)) refers to a filler that reflects electromagnetic waves. The binder component refers to a matrix component that forms a layer, and examples include a resin, a curable compound that can form a crosslinked structure by curing treatment, a monomer, and an oligomer.

The ES sheet has an elongation rate of 100% to 1500% at 100° C. In addition, in a cured sheet after treating the ES sheet at 180° C. for 2 hours, the Young's modulus at 100° C. is 100 MPa to 1000 MPa. The cured sheet referred to here is obtained by curing the ES sheet alone without bonding the ES sheet to an adherend. The condition of treating at 180° C. for 2 hours is a curing condition for specifying the characteristics of the ES sheet. That is, the curing condition for covering the wafer with the ES sheet to obtain a shield cover layer is not limited to the condition of treating at 180° C. for 2 hours. The elongation rate is calculated from “100×(length after elongation-original length)/(original length)”.

The coating target of the ES sheet is a wafer before performing a dicing process. Specific examples include a wafer on which wafer level chip size packages (WL-CSP) before dicing are formed, a wafer on which semiconductor elements before dicing are formed, a wafer on which multilayer wiring structures or the like before dicing are formed, a bare wafer, and a wafer on which a thermal oxide film obtained by high-temperature treatment of a bare wafer is formed.

The coating target surface of the ES sheet may be the element formation region surface of the wafer or the back surface thereof, and may be either single-side coating or double-side coating. With the ES sheet, the SC layer can be formed collectively on the wafer before dicing, which achieves excellent productivity. Since the ES sheet excels in followability to uneven shapes, the ES sheet is suitable for batch coating on a wafer that has half-cut grooves formed in a lattice pattern and element formation regions partitioned by the half-cut grooves and arranged in a matrix pattern. By performing batch coating to include also the half-cut grooves, the SC layer can be easily formed on the side surfaces of semiconductor devices after dicing.

The coating target region of the ES sheet may be the entire wafer surface or a part of the wafer. For example, an aspect that can be mentioned is batch coating the ES sheet on about 80% of the area of the main surface of the wafer. A bare wafer refers to a wafer before processing treatment, and examples include semiconductor substrates such as single crystal silicon, gallium arsenide, and indium phosphide. The wafer diameter and thickness are arbitrary. The bare wafer diameter is, for example, 100 mm, 150 mm, 200 mm, 300 mm, or 450 mm. The thickness of the bare wafer (semiconductor substrate) is, for example, about 400 μm to 1000 μm.

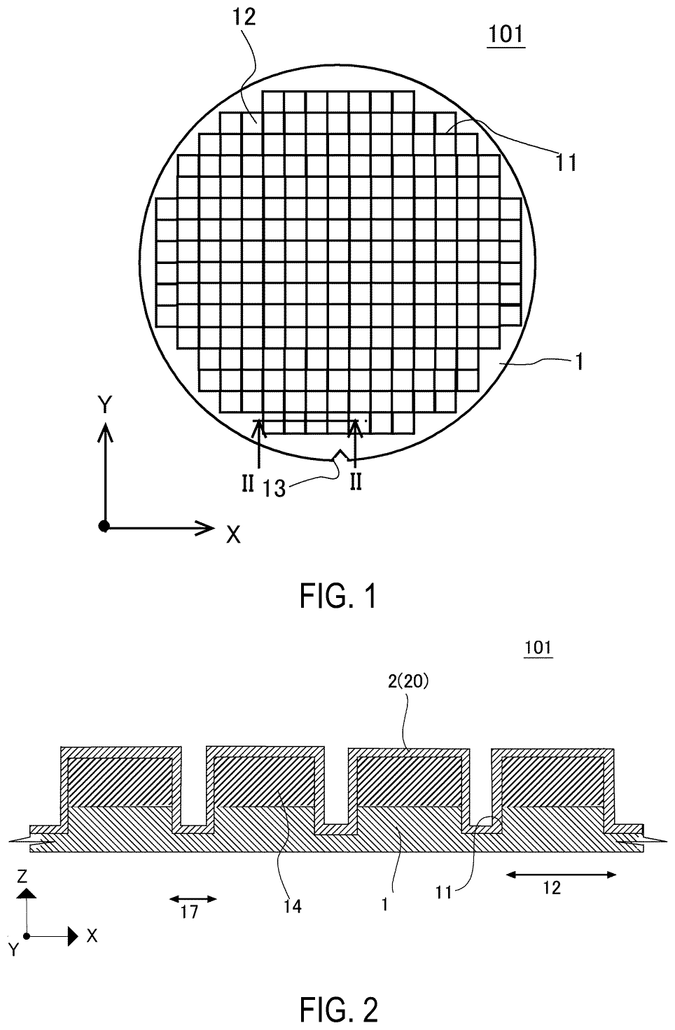

FIG. 1 shows a schematic view of an example of the shielded wafer of the present embodiment, and FIG. 2 shows a cross-sectional view taken along line II-II of FIG. 1. As shown in FIG. 2, a shielded wafer 101 has a multilayer wiring structure portion 14 formed on a semiconductor element formation wafer 1, and an SC layer 2 covering the semiconductor element formation wafer 1 and the multilayer wiring structure portion 14. With the SC layer 2, electromagnetic waves generated from semiconductor elements of the semiconductor element formation wafer 1 or wiring of the multilayer wiring structure portion 14 can be shielded. Additionally, electromagnetic waves from the outside can be shielded to prevent malfunction of semiconductor devices. The thickness of the SC layer can be appropriately designed according to the application. The thickness of the SC layer is usually about 1 μm to 300 μm. The lower limit of the thickness is more preferably 3 μm, further preferably 5 μm, and even more preferably 10 μm. The upper limit of the thickness is more preferably 150 μm, further preferably 100 μm, and even more preferably 50 μm.

As shown in FIG. 1 and FIG. 2, the shielded wafer 101 has the semiconductor element formation wafer 1, the half-cut grooves 11 formed in a lattice pattern in the X-axis and Y-axis directions of the semiconductor element formation wafer 1, the element formation regions 12 partitioned by the half-cut grooves 11 and arranged in a matrix pattern, and the SC layer 2. The element formation regions 12 are regions that are made into chips by a dicing process described later. As shown in FIG. 1, the semiconductor element formation wafer 1 is provided with a notch 13 serving as a crystal orientation indicator at an end portion of the semiconductor element formation wafer 1.

The half-cut grooves 11 are grooves formed from the upper surface of the multilayer wiring structure portion 14 to the middle of the semiconductor element formation wafer 1 in the thickness direction of the semiconductor substrate, and are formed along scribe lines 17 formed in a lattice pattern along the X-axis and Y-axis. The width of the half-cut groove 11 is, for example, 20 μm to 500 μm. The depth of the half-cut groove 11 from the upper surface of the semiconductor element formation wafer 1 is, for example, 40 μm to 600 μm. The half-cut groove 11 can be formed by known methods such as a rotating blade which is mechanical cutting, and laser grooving. The half-cut groove also includes an aspect in which the groove does not reach the semiconductor element formation wafer 1 and the groove is formed only in the multilayer wiring structure portion 14.

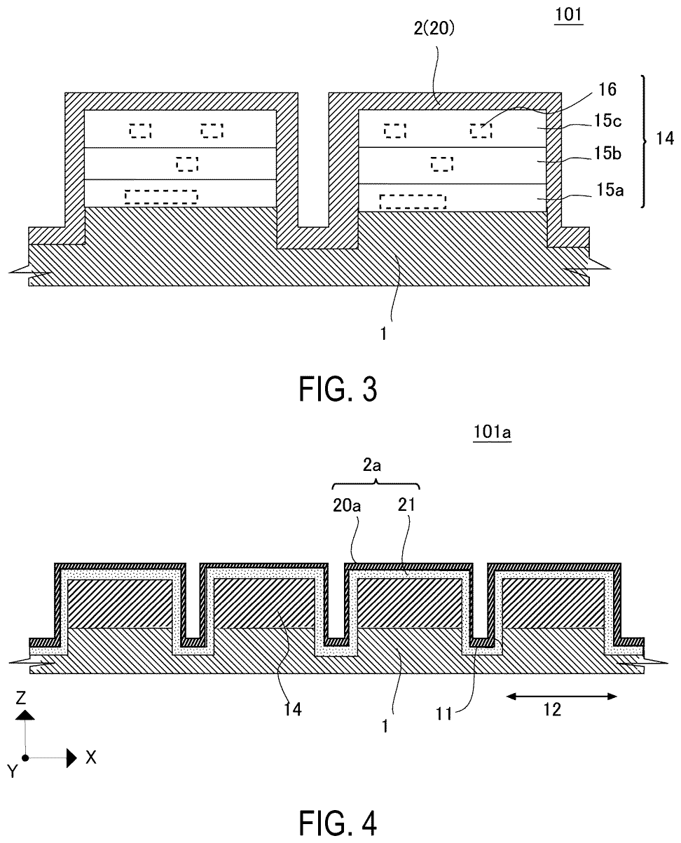

The multilayer wiring structure portion 14 has, for example, as shown in FIG. 3, a first insulating film 15a, a second insulating film 15b, and a third insulating film 15c laminated in this order, and multiple metal patterns such as wiring 16 are formed in each layer. A surface protective film (not shown) or the like may be further formed on the upper layer of the multilayer wiring structure portion 14.

The SC layer includes a single layer or multiple layers as described later, and has at least a shielding layer. The SC layer 2 shown in FIG. 2 includes a shielding layer 20. The shielding layer refers to a layer in which the shielding film including the binder component and the conductive filler (F) is cured. The shielding layer 20 may be a single layer or multiple layers. Also, the SC layer may be a laminate of a shielding layer 20a and a non-shielding layer 21 as shown in FIG. 4. The non-shielding layer 21 may be disposed on the multilayer wiring structure portion 14 side as in the example of FIG. 4, or on the opposite side. Examples of the non-shielding layer 21 include a light-shielding layer, a hard coat layer, an insulating layer, a thermal conductive layer, and a protective layer. The non-shielding layer 21 may be a single layer or multiple layers of the same type or different types.

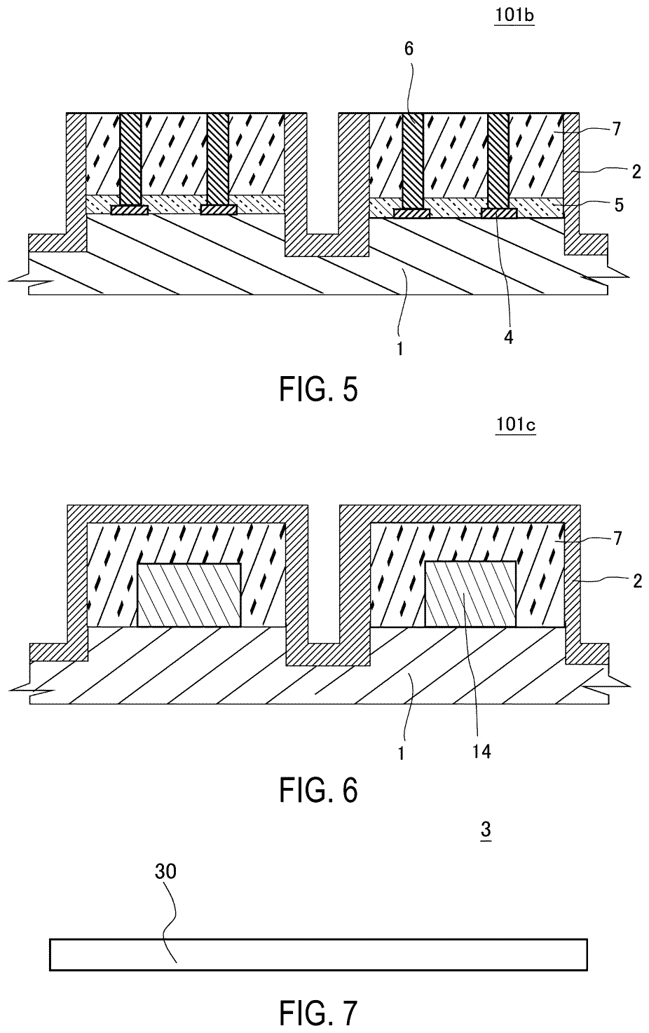

The shielded wafer may be a wafer on which wafer level chip size packages (WL-CSP) are formed. FIG. 5 shows a schematic cross-sectional view of an example of the shielded wafer of WL-CSP before dicing. As shown in the figure, a shielded wafer 101b has electrode pads 4, a surface protective film 5, electrode posts 6, a sealing resin 7, a SC layer 2, etc. on the upper surface of the semiconductor element formation wafer 1. By dicing the shielded wafer 101b, semiconductor devices whose sides are covered with the SC layer 2 are obtained. The obtained semiconductor devices are mounted on a printed circuit board (not shown) or the like via solder balls (not shown) installed on the electrode posts 6.

FIG. 6 shows a schematic cross-sectional view of another example of the shielded wafer on which WL-CSP are formed. A shielded wafer 101c has a multilayer wiring structure portion 14 on the upper surface of a semiconductor element formation wafer 1, and this multilayer wiring structure portion is sealed with a sealing resin 7. Then, the semiconductor element formation wafer 1 and the sealing resin 7 are covered with a SC layer 2. By dicing the shielded wafer 101c, semiconductor devices whose upper surface and sides are covered with the SC layer 2 are obtained (FIG. 9, etc.).

### 2. Electromagnetic Wave Shielding Sheet

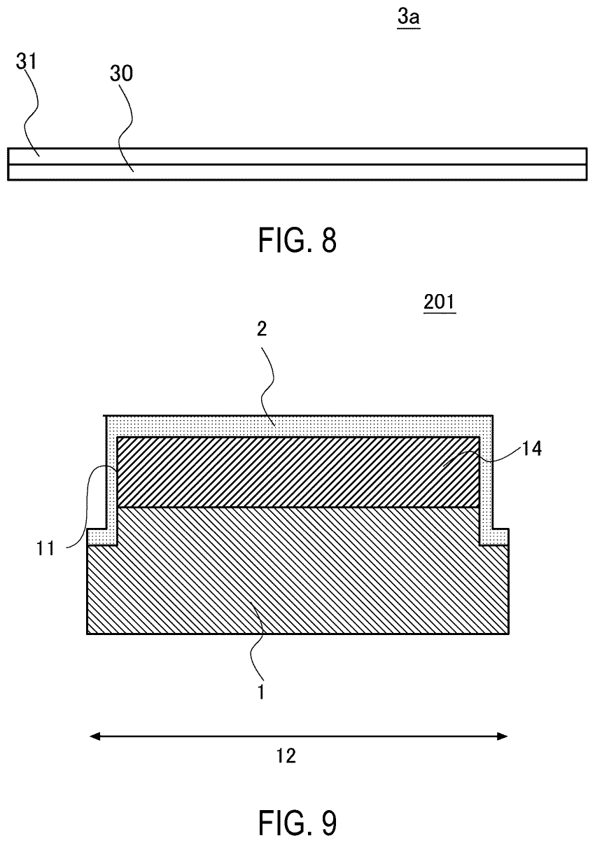

FIG. 7 shows a schematic side view of an example of the ES sheet of the present embodiment. An ES sheet 3 shown in the figure includes a shielding film 30. The shielding film 30 may be a single layer or multiple layers. The ES sheet may be an ES sheet 3a in which one or more shielding films 30 and one or more non-shielding films 31 are laminated as shown in FIG. 8. The shielding film 30 is covered to become the shielding layer 20. Also, the non-shielding film 31 is covered to become the non-shielding layer 21. Examples of the non-shielding film 31 include an insulating film, a thermal conductive film, a light-shielding film, and a hard coat film. In the case of the ES sheet having a non-shielding film, from the viewpoint of sufficiently exhibiting the shielding effect, it is preferable to sufficiently secure the thickness of the shielding film. From this viewpoint, preferably 50% to 90% of the thickness of the ES sheet is the shielding film, and more preferably 55% to 80%.

The elongation rate at 100° C. of the ES sheet is 100% to 1500%. Additionally, in the cured sheet after treating the ES sheet at 180° C. for 2 hours, the Young's modulus at 100° C. is 100 MPa to 1000 MPa. According to the ES sheet combining these, the followability to uneven shapes during pressing for batch coating of the ES sheet can be enhanced. Also, cracking of the wafer can be suppressed, and warping of the wafer after curing can be suppressed. Furthermore, peeling of the SC layer from the adherend can be suppressed, and tearing in recesses such as half-cut grooves can be effectively suppressed.

The lower limit of the elongation rate is more preferably 150%, and even more preferably 200%. In addition, the upper limit of the elongation rate is more preferably 1200%, and even more preferably 1000%. The lower limit of the Young's modulus is preferably 150 MPa, more preferably 200 MPa, and even more preferably 300 MPa. The upper limit of the Young's modulus is preferably 800 MPa, and more preferably 600 MPa. In the case of the ES sheet including a laminate of multiple films, each film does not need to satisfy the aforementioned conditions, and it is sufficient that the ES sheet satisfies the elongation rate and the Young's modulus.

The thickness of the ES sheet can be appropriately designed according to the application. The thickness of the ES sheet is usually about 2 μm to 500 μm. The lower limit of the thickness is more preferably 5 μm, even more preferably 8 μm, and still more preferably 12 μm. The upper limit of the thickness is more preferably 300 μm, even more preferably 200 μm, and still more preferably 100 μm. The ES sheet is suitable for a coating layer that is coated to follow uneven shapes as shown in FIG. 2, but may also be applied to an embedded layer in which the ES sheet is embedded (filled) in recesses.

From the viewpoint of enhancing reliability, in an electromagnetic wave shielding layer derived from the electromagnetic wave shielding sheet after the ES sheet is thermocompression bonded to the entire main surface of a silicon bare wafer at 120° C. and 5 MPa for 3 minutes, and then treated at 180° C. for 2 hours, the peeling rate in an adhesion test after performing a pressure cooker test based on JIS K5600-5-6 is preferably less than 15%, more preferably less than 10%, and even more preferably less than 5%.

The ES sheet is thermocompression bonded at 120° C. and 5 MPa for 3 minutes to the entire main surface of a 12-inch silicon bare wafer having half-cut grooves with a width of 200 am and a depth of 200 μm formed in a lattice pattern at intervals of 4000 μm, and cured at 180° C. for 2 hours, to obtain a SC layer. For the SC layer obtained, the resistance value between the center of the SC layer covering the convex portion (in the example of FIG. 6, the convex portion where the multilayer wiring structure portion 14 is sealed by the sealing resin 7) and the center of the same convex portion at an adjacent position via the half-cut groove (between shield cover layers on the adjacent convex portion) is preferably 5 mΩ to 300 mΩ. The upper limit of the resistance value is more preferably 150 mΩ, even more preferably 100 mΩ, and still more preferably 50 mΩ. The lower limit of the resistance value is more preferably 7 mΩ, even more preferably 10 mΩ, and still more preferably 15 mΩ.

The shielding film 30 includes the binder component and the conductive filler (F) as described above. The shielding film 30 becomes the shielding layer 20, which is a cured product, by thermosetting treatment. The thickness of the shielding film 30 is, for example, 5 μm to 100 μm. From the viewpoint of achieving both processability to wafers and electromagnetic wave shielding properties, the lower limit of the thickness of the shielding film 30 is preferably 7 μm, more preferably 10 μm, and even more preferably 20 μm. On the other hand, the upper limit of the thickness of the shielding film is preferably 90 μm, more preferably 75 μm, and even more preferably 50 μm.

### 2-1. Shielding Film

The binder component of the shielding film 30 plays a role in holding the filler (F) in the film and forming the film. The binder component includes a component that forms a crosslinked structure by curing treatment.

A suitable example of the binder component is a combination of a high molecular weight resin (P) having a weight average molecular weight (Mw) of 10,000 or more and a curable compound (C) having an Mw of 5,000 or less. By combining the high molecular weight resin (P) having an Mw of 10,000 or more and the curable compound (C) having an Mw of 5,000 or less, it is possible to achieve excellent film-forming properties of the ES sheet while achieving excellent followability to uneven shapes and coating properties (embedding properties) for recesses such as half-cut grooves. The curable compound (C) may be a low molecular compound in addition to an oligomer component. In the case of a low molecular compound, Mw is read as molecular weight.

The upper limit of the Mw of the high molecular weight resin (P) is preferably 300,000, more preferably 250,000, even more preferably 200,000, and still more preferably 150,000, from the viewpoint of enhancing coating properties for half-cut grooves. The lower limit of the Mw of the high molecular weight resin (P) is more preferably 40,000, even more preferably 60,000, and still more preferably 80,000, from the viewpoint of adjusting the elongation rate at 100° C. As the Mw increases, the elongation rate at 100° C. tends to increase.

Examples of the high molecular weight resin (P) include polyurethane resin, polyurethane urea resin, phenoxy resin, acrylic resin, polyester resin, polyamide resin, polystyrene resin, polycarbonate resin, polyamideimide resin, polyesteramide resin, polyetherester resin, and polyimide resin. The high molecular weight resin (P) is used alone or in combination of two or more types.

The high molecular weight resin (P) may be any of thermoplastic resin, photocurable resin, and thermosetting resin, but preferably includes a thermosetting resin that can crosslink with the curable compound (C) from the viewpoint of obtaining a highly reliable SC layer. The thermosetting resin is preferably 50% by mass or more, more preferably 70% by mass or more, even more preferably 80% by mass or more, still more preferably 90% by mass or more, and may be 100% by mass, relative to 100% by mass of the high molecular weight resin (P).

The high molecular weight resin (P) preferably includes a thermosetting resin having reactive functional groups that react with the functional groups of the curable compound (C) to form a crosslinked structure. Examples of the reactive functional groups of the high molecular weight resin (P) include carboxyl group, hydroxyl group, amino group, epoxy group, oxetanyl group, oxazoline group, oxazine group, aziridine group, thiol group, isocyanate group, blocked isocyanate group, and silanol group. Among these, carboxyl group and hydroxyl group are suitable in terms of storage stability of the electromagnetic wave shielding sheet.

The acid value of the high molecular weight resin (P) is preferably 3 mgKOH/g to 30 mgKOH/g. By setting the acid value within the above range, adhesion to the wafer is improved. The acid value is more preferably 4 mgKOH/g to 25 mgKOH/g, and even more preferably 5 mgKOH/g to 20 mgKOH/g. Examples of the high molecular weight resin (P) having suitable thermosetting properties include the aforementioned resins having carboxyl group and/or hydroxyl group (polyurethane resin, polyurethane urea resin, phenoxy resin, acrylic resin, polyester resin, polyamide resin, epoxy resin, polystyrene resin, polycarbonate resin, polyamideimide resin, polyesteramide resin, polyetherester resin, and polyimide resin).

From the viewpoint of combining the elongation rate at 100° C. (100% to 1500%) of the ES sheet and the above-described Young's modulus at 100° C. (100 MPa to 1000 MPa) after curing treatment, the Tg of the high molecular weight resin (P) is preferably −20° C. to 40° C., more preferably −10° C. to 30° C., and even more preferably 0° C. to 20° C. In the case of two or more types of high molecular weight resin (P), it is preferable that the high molecular weight resin (P) which is the main component with the largest blending amount satisfies −20° C. to 40° C., and the main component is preferably 50% by mass or more, more preferably 70% by mass or more, and even more preferably 90% by mass or more, relative to the high molecular weight resin (P).

The curable compound (C) having an Mw of 5,000 or less plays a role in forming a crosslinked structure, and also plays a role in enhancing flexibility when coating the ES sheet and imparting excellent followability to uneven shapes. Moreover, after curing, a highly reliable SC layer can be obtained by constructing a crosslinked network.

The content ratio of the curable compound (C) is preferably 5 parts by mass to 100 parts by mass relative to 100 parts by mass of the high molecular weight resin (P). The lower limit of the content ratio of the curable compound (C) is more preferably 10 parts by mass, even more preferably 12 parts by mass, still more preferably 15 parts by mass, and particularly preferably 20 parts by mass. The upper limit of the content ratio of the curable compound (C) is more preferably 80 parts by mass, even more preferably 70 parts by mass, still more preferably 60 parts by mass, and particularly preferably 50 parts by mass.

Examples of the curable compound (C) include epoxy group-containing compound (E), isocyanate compound, carbodiimide group-containing compound, aziridine compound, acid anhydride group-containing compound, dicyandiamide compound, amine compounds such as aromatic diamine compound, organometallic compounds such as metal chelate compound, maleimide group-containing compound, and phenol compounds such as phenol novolac resin. Among these, it is preferable to include the epoxy group-containing compound (E) from the viewpoint of enhancing flexibility during coating of the ES sheet and enhancing reliability after coating. From the viewpoint of adjusting the curing rate of semi-curing (B-stage curing) and full curing (C-stage curing), it is preferable to use the epoxy group-containing compound (E) in combination with a curable compound other than the epoxy group-containing compound (E). A suitable example is a combination of the epoxy group-containing compound (E) with one or more selected from aziridine compound, isocyanate compound, and maleimide group-containing compound.

In 100% by mass of the curable compound (C), the content ratio of the epoxy group-containing compound (E) is preferably 50% by mass or more, more preferably 70% by mass or more, even more preferably 85% by mass or more, and still more preferably 90% by mass or more. The upper limit of the content ratio may be 100% by mass.

In 100% by mass of the curable compound (C), the other curable compound used in combination with the epoxy group-containing compound (E) is preferably 50% by mass or less, more preferably 30% by mass or less, even more preferably 15% by mass or less, and still more preferably 10% by mass or less. From the viewpoint of bringing out the effect of the other curable compound used in combination, the lower limit is preferably 0.1% by mass, more preferably 0.3% by mass, and even more preferably 0.4% by mass.

In 100 parts by mass of the binder component, the total content of the high molecular weight resin (P) and the epoxy group-containing compound (E) is preferably 70 parts by mass or more, more preferably 80 parts by mass or more, even more preferably 90 parts by mass or more, and may be 100 parts by mass.

The epoxy group-containing compound (E) is not particularly limited as long as the epoxy group-containing compound (E) has an epoxy group, but from the viewpoint of adjusting the Young's modulus at 100° C. of the cured sheet after treating the electromagnetic wave shielding sheet at 180° C. for 2 hours to 100 MPa to 1000 MPa, a polyfunctional epoxy group-containing compound (E) having two or more functional groups is preferable. In hot pressing or the like, the epoxy groups of the epoxy group-containing compound (E) thermally crosslink with carboxyl groups or hydroxyl groups of the thermosetting resin to obtain a crosslinked structure. From the viewpoint of enhancing flexibility and followability in the coating process of the ES sheet and effectively bringing out stress relaxation after coating, an epoxy group-containing compound (E) that shows a liquid state at normal temperature and normal pressure is suitable as the epoxy group-containing compound (E).

From the viewpoint of easily obtaining an SC layer having the above Young's modulus, the epoxy equivalent of the epoxy group-containing compound (E) is preferably 110 g/eq to 1000 g/eq. The lower limit of the epoxy equivalent is more preferably 115 g/eq, and even more preferably 150 g/eq. The upper limit of the epoxy equivalent is more preferably 900 g/eq, even more preferably 750 g/eq, still more preferably 500 g/eq, and particularly preferably 280 g/eq. From the viewpoint of more effectively enhancing flexibility, the epoxy group-containing compound (E) preferably includes 10 parts by mass to 80 parts by mass relative to 100 parts by mass of the high molecular weight resin (P). By setting the blending amount as described above, the flexibility of the shielding film can be enhanced. By setting the epoxy equivalent of the epoxy group-containing compound (E) to 110 g/eq to 1000 g/eq, the crosslinking density in the semi-cured product of the shielding film can be adjusted to effectively enhance edge coating properties. Here, “edge” refers to sides and corners of end portions of uneven portions. The epoxy equivalent is expressed as the number of grams of epoxy compound containing one gram equivalent of epoxy groups [g/eq], and is determined according to the method specified in JIS K 7236.

Examples of the epoxy group-containing compound (E) include glycidyl ether type epoxy compounds, glycidyl amine type epoxy compounds, glycidyl ester type epoxy compounds, and cyclic aliphatic (alicyclic) epoxy compounds.

Examples of glycidyl ether type epoxy compounds include bisphenol A type epoxy compounds, bisphenol F type epoxy compounds, bisphenol S type epoxy compounds, bisphenol AD type epoxy compounds, cresol novolac type epoxy compounds, phenol novolac type epoxy compounds, α-naphthol novolac type epoxy compounds, bisphenol A type novolac type epoxy compounds, dicyclopentadiene type epoxy compounds, tetrabromobisphenol A type epoxy compounds, brominated phenol novolac type epoxy compounds, tris(glycidyloxyphenyl)methane, and tetrakis(glycidyloxyphenyl)ethane.

Examples of glycidyl amine type epoxy compounds include tetraglycidyl diaminodiphenylmethane, triglycidyl para-aminophenol, triglycidyl meta-aminophenol, and tetraglycidyl meta-xylylenediamine.

Examples of glycidyl ester type epoxy compounds include diglycidyl phthalate, diglycidyl hexahydrophthalate, and diglycidyl tetrahydrophthalate.

Examples of cyclic aliphatic (alicyclic) epoxy compounds include epoxycyclohexylmethyl-epoxycyclohexanecarboxylate and bis(epoxycyclohexyl)adipate. Additionally, liquid epoxy compounds can be suitably used.

The epoxy group-containing compound (E) preferably also has other functional groups besides epoxy groups. Examples of other functional groups include hydroxyl groups, secondary amino groups, and tertiary amino groups. By using the epoxy group-containing compound (E) having such other functional groups in addition to epoxy groups having two or more functional groups, the crosslinking density under predetermined curing conditions is effectively increased, and PCT resistance is enhanced. Furthermore, by including hydroxyl groups and/or amino groups, adhesion to adherend such as wafer can be enhanced, and as a result, good PCT resistance and adhesiveness can be simultaneously satisfied.

The binder component may include components other than the aforementioned within a range that does not depart from the spirit of the disclosure. For example, the binder component may include resins such as tackifying resins having an Mw less than 10,000, thermoplastic resins, thermosetting resins, and photocurable resins. Examples of tackifying resins include rosin-based resins, terpene-based resins, alicyclic petroleum resins, and aromatic petroleum resins.

Examples of the conductive filler (F) include metal particles, conductive metal oxide particles, particles having conductive polymers, and metal-coated particles.

Examples of metal particles include metal powders such as gold, silver, copper, palladium, aluminum, nickel, iron, titanium, manganese, zinc, tungsten, platinum, lead, and tin, alloy powders such as solder, steel, and stainless steel, and core-shell types such as silver-coated copper powder, gold-coated copper powder, silver-coated nickel powder, and gold-coated nickel powder. Excellent conductivity can be obtained by using a filler (F) containing silver. The content of silver in silver-coated copper is preferably 6% by mass to 20% by mass, more preferably 8% by mass to 17% by mass, and still more preferably 10% by mass to 15% by mass, in 100% by mass of the filler (F). In the case of core-shell type fillers, the coating ratio of the coating layer to the core portion is preferably 60% by mass or more on average, more preferably 70% by mass or more, and even more preferably 80% by mass or more, in 100% by mass of the entire surface.

Examples of metal oxide-based particles include zinc oxide, indium oxide, and tin oxide having conductivity.

Examples of particles having conductive polymers include polyacetylene particles, polythiophene particles, polypyrrole particles, or particles coated with these on the surface.

Examples of metal-coated particles include particles in which the surface of resin particles is coated with metals such as gold and silver, and particles in which the surface of inorganic particles such as glass and ceramics is metal-coated.

Examples of conductive carbon materials include carbon black, acetylene black, ketjen black, graphite, carbon nanotubes, graphene, fullerene, carbon nanocoils, carbon microcoils, carbon fibers, etc.

Examples of the shape of the filler (F) include flake-shaped (scale-shaped), dendritic, fibrous, needle-shaped, or spherical fillers. The filler (F) is used alone or in combination. In the case of combined use, examples include a combination of flake-shaped filler and dendritic filler, a combination of flake-shaped filler, dendritic filler, and spherical filler, and a combination of flake-shaped filler and spherical filler. Among these, from the viewpoint of enhancing the edge coating properties of the SC layer, flake-shaped filler alone or a combination of flake-shaped filler and dendritic filler is more preferable.

The average particle diameter D₅₀ of the flake-shaped filler is preferably 0.5 μm to 50 μm, more preferably 1 μm to 30 μm, still more preferably 2 μm to 20 μm, and particularly preferably 2 μm to 10 μm. Similarly, the preferable range of the average particle diameter D₅₀ of the dendritic filler (F) is preferably 2 μm to 100 μm, more preferably 2 μm to 80 μm, still more preferably 3 μm to 50 μm, and particularly preferably 5 μm to 20 μm.

The specific surface area of the flake-shaped filler is preferably 0.2 m²/g to 4.0 m²/g, more preferably 0.4 m²/g to 3.5 m²/g, still more preferably 0.5 m²/g to 3.0 m²/g, and particularly preferably 1.0 m²/g to 2.5 m²/g. Similarly, the preferable range of the specific surface area of the dendritic filler is preferably 0.2 m²/g to 2.0 m²/g, more preferably 0.3 m²/g to 1.8 m²/g, still more preferably 0.4 m²/g to 1.6 m²/g, and particularly preferably 0.5 m²/g to 1.5 m²/g.

The content ratio of the filler (F) is preferably 45% by mass to 85% by mass relative to 100% by mass of the sheet from the viewpoint of obtaining excellent electromagnetic wave shielding properties. The lower limit is more preferably 50% by mass, and even more preferably 55% by mass. The upper limit is more preferably 82% by mass, and even more preferably 80% by mass.

The product of the average specific surface area [m²/g] of the filler (F) and the content [g] of the filler (F) relative to 100 parts by mass of the binder component is preferably 50 m² to 1200 m², more preferably 100 m² to 1000 m², even more preferably 200 m² to 800 m², and particularly preferably 300 m² to 600 m² from the viewpoint of obtaining excellent electromagnetic wave shielding properties and adhesion to the wafer.

The shielding film may include an electromagnetic wave absorbing filler in addition to the conductive filler (F). Examples of the electromagnetic wave absorbing filler include dielectric loss electromagnetic wave absorbing materials such as carbon particles, or magnetic loss electromagnetic wave absorbing materials such as ferrite and soft magnetic metal powder.

Examples of the electromagnetic wave absorbing filler include iron alloys such as iron, Fe—Ni alloy, Fe—Co alloy, Fe—Cr alloy, Fe—Si alloy, Fe—Al alloy, Fe—Cr—Si alloy, Fe—Cr—Al alloy, and Fe—Si—Al alloy, ferrite materials such as Mg—Zn ferrite, Mn—Zn ferrite, Mn—Mg ferrite, Cu—Zn ferrite, Mg—Mn—Sr ferrite, and Ni—Zn ferrite, as well as carbon fillers. Examples of carbon fillers include fillers composed of acetylene black, ketjen black, furnace black, carbon black, carbon fiber, and carbon nanotube, graphene filler, graphite filler, and carbon nanowall.

The ES sheet is particularly suitable for applications involving batch coating for wafers having half-cut grooves formed therein. Additionally, the ES sheet can be applied to all applications where it is desired to attach the ES sheet to an adherend to impart electromagnetic wave shielding properties. The ES sheet can also exhibit a shielding effect against the sides of semiconductor devices. Moreover, since batch coating is possible, design flexibility is enhanced, which is excellent in versatility.

The elongation rate at 100° C. of the ES sheet can be adjusted by the type, molecular weight, content ratio, and functional group of the binder component of the ES sheet. For example, the elongation rate can be adjusted by the blending amounts of the high molecular weight resin (P) and the epoxy group-containing compound (E). The elongation rate tends to increase by increasing the Mw of the high molecular weight resin (P). Also, the elongation rate tends to increase by lowering the Tg of the high molecular weight resin (P). By setting the epoxy equivalent of the epoxy group-containing compound (E) within the aforementioned range, the elongation rate at 100° C. of the ES sheet can be adjusted. Additionally, the elongation rate can be adjusted by a combination of the high molecular weight resin (P) and the epoxy group-containing compound (E).

The Young's modulus at 100° C. of the cured sheet after treating the ES sheet at 180° C. for 2 hours tends to increase by increasing the filler amount. Additionally, the Young's modulus tends to increase by increasing the Tg of the high molecular weight resin (P) or by increasing the acid value.

As an alternative to or in combination with the above method, a method of controlling by the type and addition amount of the filler (F) may be a method for setting the Young's modulus at 100° C. to 100 MPa to 1000 MPa in the cured sheet after treating the ES sheet at 180° C. for 2 hours. Changing the average particle diameter D₅₀, BET (Brunauer-Emmett-Teller) specific surface area, tap density, and surface treatment of the filler (F) is also effective for controlling the Young's modulus.

As a method for setting the peeling rate to less than 15% in the adhesion test after performing a pressure cooker test based on JIS K5600-5-6 on the SC layer derived from the ES sheet after thermocompression bonding the ES sheet to the entire main surface of a silicon bare wafer at 120° C. and 5 MPa for 3 minutes and treating at 180° C. for 2 hours, the peeling rate can be adjusted by the types and blending amounts of the high molecular weight resin (P) and the epoxy group-containing compound (E). As the Mw of the high molecular weight resin (P) increases, the internal cohesive force within the sheet can be enhanced, so the peeling rate tends to decrease. Additionally, as the acid value of the high molecular weight resin (P) increases, the interaction at the adherend interface such as wafer can be enhanced, so the peeling rate tends to decrease. Moreover, the adhesive force can be adjusted by adjusting the acid value and Mw of the high molecular weight resin (P) and the epoxy equivalent of the epoxy group-containing compound (E).

The shielding film can contain organic fillers and inorganic fillers other than the filler (F), and various additives within a range that does not depart from the spirit of the disclosure. Specifically, the shielding film may include monomers, oligomers, curing accelerators, curing retarders, silane coupling agents, colorants, flame retardants, antistatic agents, antioxidants, softeners, surface modifiers, lubricants, antiblocking agents, adhesion improvers, etc.

### 2-2. Non-Shielding Film

The non-shielding film includes at least a binder component. The non-shielding film may include organic fillers and/or inorganic fillers. By compositing organic fillers and inorganic fillers with the binder component, the properties of the binder component can be improved. For example, mechanical properties, thermal properties, processability, flame retardancy, transparency, refractivity, heat dissipation, dispersibility, etc. can be imparted.

Examples of inorganic fillers include inorganic compounds such as silica, alumina, titanium oxide, zinc oxide, antimony trioxide, magnesium oxide, tin oxide, zirconium oxide, magnesium hydroxide, barium sulfate, calcium carbonate, talc, kaolinite, mica, sericite, montmorillonite, bentonite, basic magnesium carbonate, boron nitride, aluminum nitride, and titanium nitride.

Suitable examples of the binder component include the same resins as for the shielding film. The filler can be appropriately selected according to the function of the non-shielding film. For example, in the case of imparting thermal conductivity to the non-shielding film, in addition to conductive fillers, nitrides such as boron nitride, aluminum nitride, and gallium nitride; metal oxides such as aluminum oxide, silicon oxide (silicon dioxide), titanium oxide, zirconium oxide, zinc oxide, tin oxide, copper oxide, and nickel oxide; metal hydroxides and hydrated metal compounds such as aluminum hydroxide, boehmite, magnesium hydroxide, calcium hydroxide, zinc hydroxide, silicic acid, iron hydroxide, copper hydroxide, barium hydroxide, zirconium oxide hydrate, tin oxide hydrate, basic magnesium carbonate, hydrotalcite, dawsonite, borax, and zinc borate; carbides such as silicon carbide, boron carbide, carbon nitride, and calcium carbide; carbonates such as calcium carbonate; titanates such as barium titanate and potassium titanate; carbon-based materials such as carbon black, carbon tubes (carbon nanotubes), carbon fiber, and diamond; glass; and other inorganic materials can be exemplified.

### 2-3. Manufacturing Method of Electromagnetic Wave Shielding Sheet

The manufacturing method of the ES sheet will be described below. However, the manufacturing method of the ES sheet is not limited to the following method.

First, a resin composition for obtaining films constituting the ES sheet is prepared. The resin composition for obtaining the shielding film is obtained by mixing the filler (F), a binder component, a solvent, etc. The mixing method is not limited as long as uniform mixing can be achieved. The resin composition for obtaining non-shielding films such as protective film is obtained by mixing a binder component, a solvent, etc.

A mixing device may be used to enhance the uniform dispersibility of the filler. Examples include stirring devices equipped with blades (Henschel mixer, pressure kneader, Banbury mixer, planetary mixer, etc.), grinding devices equipped with media (ball mill, attritor, basket mill, sand mill, sand grinder, dyno mill, dispermat, SC mill, spike mill, or agitator mill, etc.), and dispersion devices equipped with other mechanisms (microfluidizer, nanomizer, ultimizer, ultrasonic homogenizer, dissolver, disper, high-speed impeller, rotation-revolution stirrer, colloid mill, thin-film swirl high-speed mixer, etc.). Also, mixing may be performed while degassing.

The viscosity of the resin composition may be appropriately set according to the desired film thickness. The shielding film is obtained by applying the prepared resin composition on a release substrate and performing heat drying. Similarly, the non-shielding film is also obtained by applying the prepared resin composition on a release substrate and performing heat drying. Examples of methods for applying the resin composition include gravure coating method, kiss coating method, die coating method, lip coating method, comma coating method, blade method, roll coating method, knife coating method, spray coating method, bar coating method, spin coating method, dip coating method, etc.

In the case of the ES sheet including only the shielding film, the ES sheet is obtained by peeling the film from the release substrate. Further, in the case of the ES sheet having a laminated configuration of shielding film/non-shielding film, the films may be laminated to be bonded together. Also, a laminate may be obtained by applying the resin composition for forming the non-shielding film on the shielding film formed on the release substrate and performing heat drying. Moreover, a laminate may be obtained by applying the resin composition for forming the shielding film on the non-shielding film formed on the release substrate and performing heat drying. The non-shielding film is, for example, a protective film.

### 3. Semiconductor Device and Manufacturing Method Thereof

FIG. 9 shows a schematic cross-sectional view of an example of main parts of the semiconductor device obtained by dicing the shielded wafer. A semiconductor device 201 is obtained by dicing the shielded wafer in units of element formation regions, and an SC layer 2 obtained by heating and curing the ES sheet is coated from an element formation region 12 to half-cut grooves 11. The SC layer 2 may be heated and cured before dicing, or may be heated and cured after dicing.

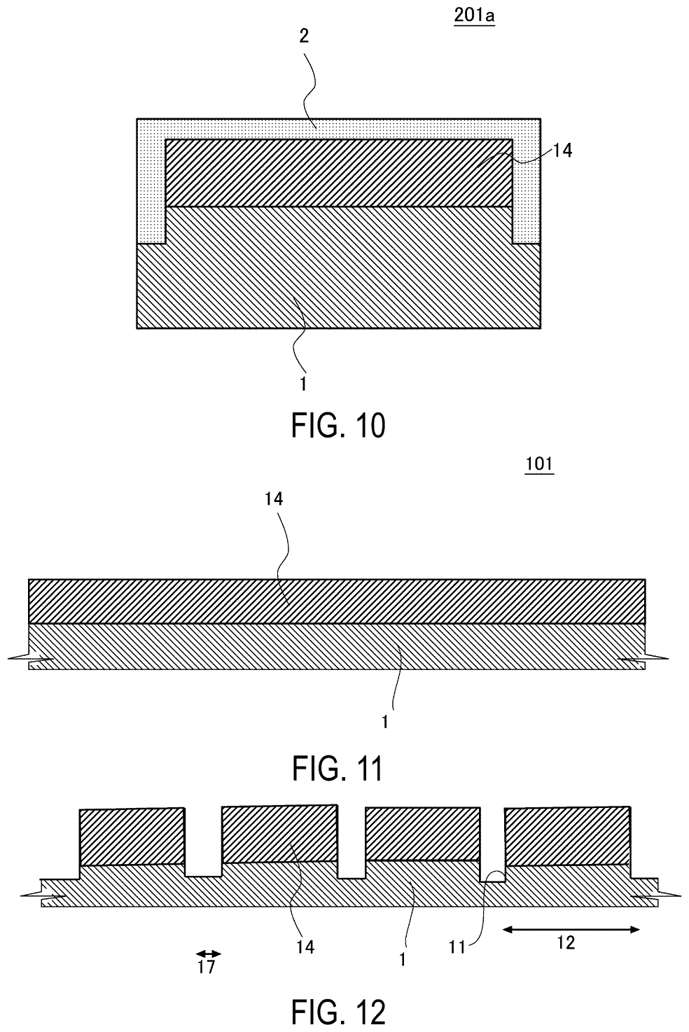

FIG. 10 shows a schematic cross-sectional view of an example of the semiconductor device according to a modification example. The example of FIG. 9 illustrates that the SC layer 2 is coated along the sidewalls and bottom of the half-cut groove, but as shown in FIG. 10, the entire half-cut groove may be filled with the SC layer 2. In the case of the half-cut groove having a narrow width, a method of filling the half-cut groove with the SC layer 2 and dicing the wafer and the SC layer 2 along scribe lines by dicing cut is effective.

An example of the manufacturing method of the semiconductor device will be described below. However, the manufacturing method of the semiconductor device of the disclosure is not limited to the following method.

First, in order to form a circuit pattern on a bare wafer, the bare wafer is subjected to high-temperature treatment to form an oxide film on the bare wafer surface. Next, a photosensitive photoresist, an insulating layer, a wiring pattern, etc. are formed to form a semiconductor element formation wafer 1, and thereafter, a multilayer wiring structure portion 14, etc. is formed (see FIG. 11). Next, a surface protective film is formed as necessary. Thereafter, half-cut grooves 11 are formed along scribe lines 17 (see FIG. 1) from the surface of the semiconductor element formation wafer 1 to the middle of the wafer (see FIG. 12). The half-cut grooves can be formed by mechanical cutting such as a rotating blade or by laser grooving.

As a specific example, the wafer is fixed in a state of being vacuum-adsorbed to a vacuum chuck of a dicing device. Then, from the surface side of the wafer, dicing is performed along X-direction scribe lines and Y-direction scribe lines using a dicing blade to form the half-cut grooves 11 that reach into the wafer.

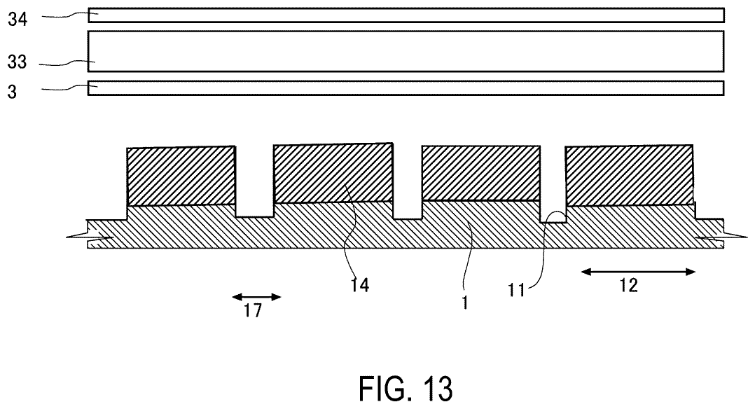

Next, an ES sheet 3 is placed on the semiconductor element formation wafer 1 in which the half-cut grooves 11 are formed. In order to enhance the coating properties of the ES sheet 3 to the half-cut grooves 11, it is preferable to place a cushion sheet 33 on the ES sheet 3 as shown in FIG. 13. In addition, a reinforcing sheet 34 may be laminated on the upper layer of the cushion sheet 33 as necessary.

By providing the cushion sheet 33, the followability of the ES sheet 3 to the half-cut grooves 11 is enhanced. The cushion material uses a layer that melts during hot pressing and has release properties. The reinforcing sheet can transmit the pressing force to the cushion sheet to enhance the embedding properties of the ES sheet to the stepped portions of the adherend.

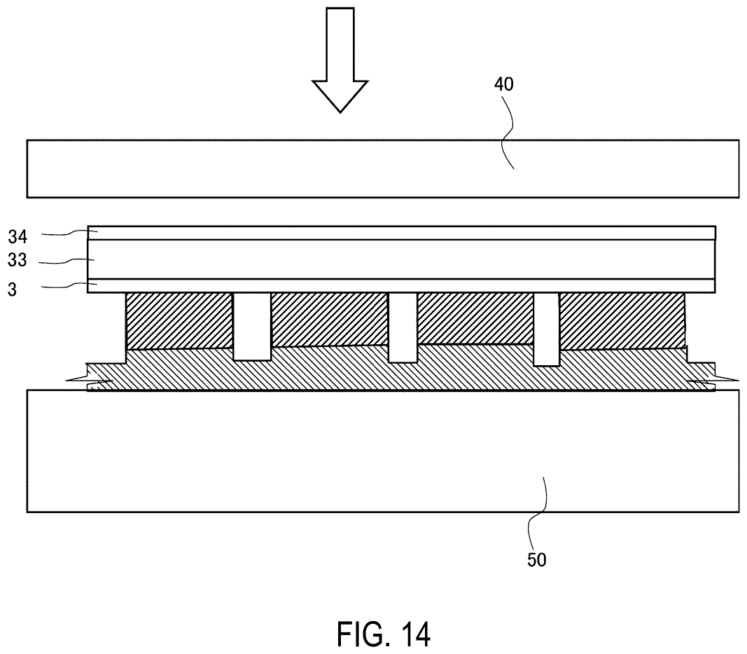

The semiconductor element formation wafer 1 is fixed to a vacuum suction stage 50 (see FIG. 14), and the laminate of ES sheet 3/cushion sheet 33/reinforcing sheet 34 is thermocompression bonded. Before thermocompression bonding, the ES sheet 3 may be temporarily attached to the upper surface of the semiconductor element formation wafer 1. The temporary attachment method can be performed, for example, by lightly hot-pressing the ES sheet 3 to the entire surface or end portions of the semiconductor element formation wafer 1 with a heat source.

The reinforcing sheet 34 can be appropriately selected from resin films, metal plates, and the like. Examples include plastic sheets such as polyethylene terephthalate, polyethylene naphthalate, polyvinyl fluoride, polyvinylidene fluoride, rigid polyvinyl chloride, polyvinylidene chloride, nylon, polyimide, polystyrene, polyvinyl alcohol, ethylene-vinyl alcohol copolymer, polycarbonate, polyacrylonitrile, polybutene, flexible polyvinyl chloride, polyethylene, polypropylene, polyurethane resin, ethylene vinyl acetate copolymer, and polyvinyl acetate; papers such as glassine paper, high-quality paper, kraft paper, and coated paper; various nonwoven fabrics, synthetic paper, metal foil, and composite films combining these. Among these, from the viewpoint of handling properties and cost, any of polyethylene terephthalate, polyester, polycarbonate, polyimide, and polyphenylene sulfide is preferable. Furthermore, polyethylene terephthalate and polyimide are more preferable.

A cushion layer 33′ obtained from the cushion sheet 33 preferably has a release layer formed on the bonding surface with the ES sheet in order to facilitate peeling from the SC layer after hot pressing. Examples of such a release layer include polypropylene, polymethylpentene, cyclic olefin polymer, silicone, and fluorine resin.

Commercially available cushion layers include “CR1012”, “CR1012MT4”, “CR1031”, “CR1033”, “CR1040”, “CR2031MT4”, etc. manufactured by Mitsui Tohcello. These commercially available cushion layers often have a layer configuration in which both surfaces of the cushion layer are sandwiched with polymethylpentene as release layers. In this specification, the integrated configuration including the release layer is called a cushion sheet. By laminating a reinforcing sheet on one side, the embedding properties and substrate cracking can be improved.

The thickness of the cushion sheet is preferably 50 μm to 300 μm, more preferably 75 μm to 250 μm, and even more preferably 100 μm to 200 μm. By setting the thickness to 50 μm or more, embedding properties can be improved. By setting the thickness to 300 μm or less, the handling properties of the ES sheet can be made favorable. The thickness of the cushion layer is a value including the release layer in the case of including a release layer.

The thickness of the reinforcing sheet 34 is preferably 20 μm or more, more preferably m or more, and even more preferably 38 μm or more. By setting the thickness of the reinforcing sheet to 20 μm or more, the strength of the reinforcing sheet is improved, so embedding properties, release properties, and handling properties are further improved. The thickness of the reinforcing sheet is not particularly limited, but in the case of 250 μm or less, the release properties and handling properties of the ES sheet are improved, which is preferable.

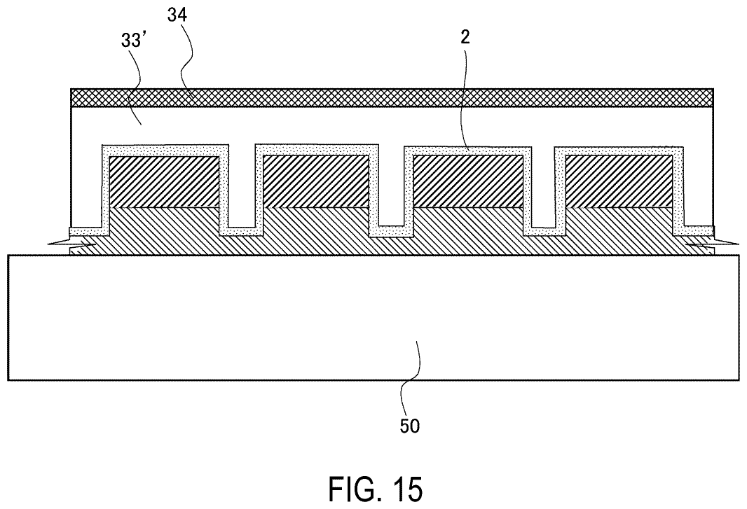

By thermocompression bonding the ES sheet 3 to the wafer, the SC layer 2 is formed on the semiconductor element formation wafer 1. A press substrate 40 is lowered from above the reinforcing sheet 34 to perform hot pressing (see FIG. 14). The ES sheet 3 is stretched along the half-cut grooves provided in the wafer by pressing due to melting of the cushion sheet 33, and is coated following the multilayer wiring structure portion 14 and the half-cut grooves 11, to form the SC layer 2 (see FIG. 15).

The temperature of the hot pressing process is preferably equal to or higher than the melting temperature of the cushion sheet 33 and lower than the melting temperature of the reinforcing sheet 34. By setting the temperature as described above, the strength of the reinforcing sheet can be maintained while melting the cushion sheet. The heating temperature of the hot pressing process is preferably 100° C. or higher, more preferably 110° C. or higher, and even more preferably 120° C. or higher. Although the upper limit value depends on the heat resistance of the multilayer wiring structure portion 14, the upper limit value is preferably 220° C. or lower, more preferably 200° C. or lower, and even more preferably 180° C. or lower.

The pressure of the hot pressing process is appropriately set according to the thickness of the wafer so that the wafer does not crack. For example, the pressure is about 1 MPa to 15 MPa, more preferably 1.5 MPa to 10 MPa, and even more preferably 2 MPa to 5 MPa. The hot pressing time is, for example, about 1 minute to 2 hours. In the process of hot pressing, the curing treatment may be completed, or a process of performing curing treatment after hot pressing may be separately provided. The thermosetting resin in the binder component may be partially cured or substantially completely cured before hot pressing as long as the thermosetting resin can flow. As the hot pressing device, a pressing type hot pressing device, a transfer molding device, a compression molding device, a vacuum pressure forming device, etc. can be used.

Thereafter, the press substrate 40 is released, and the cushion layer 33′ and the reinforcing sheet 34 are removed. Through these processes, a shielded wafer as shown in FIG. 2 is obtained. As shown in FIG. 5, the upper surface may be removed by etching.

The above embodiment illustrates an example where the ES sheet 3, the cushion sheet 33, and the reinforcing sheet 34 are used in a stacked manner, but a laminate bonded in any combination may be used. For example, a laminate in which ES sheet/cushion sheet/reinforcing sheet, ES sheet/cushion sheet, or cushion sheet/reinforcing sheet are bonded together may be used. By bonding the reinforcing sheet and the cushion sheet, the peelability can be significantly enhanced.

Subsequently, a dicing process is performed along the scribe lines. Specifically, the shielded wafer is diced. The dicing method can be performed by a rotating blade which is mechanical cutting, laser grooving, etc., similarly to half-cut grooves. In addition, cutting may be performed by polishing the back surface side of the wafer to reduce the wafer thickness down to the half-cut grooves.

### EXAMPLES

The disclosure will be described more specifically by examples below, but the scope of the disclosure is not limited in any way. In the examples, “parts” and “%” represent “parts by mass” and “% by mass”.

### (a) Measurement Method

The numerical values obtained in this example are values obtained by the following methods.

### (i) Weight Average Molecular Weight (Mw)

The measurement of Mw used GPC (Gel Permeation Chromatograph) “HPC-8020” manufactured by Tosoh Corporation. GPC is a liquid chromatograph that separates and quantifies substances dissolved in a solvent (THF; tetrahydrofuran) based on differences in molecular size. The measurement was performed using two “LF-604” columns (manufactured by Showa Denko: GPC column for rapid analysis: 6 mm ID×150 mm size) connected in series, under conditions of flow rate 0.6 mL/min and column temperature of 40° C., and the determination of weight average molecular weight (Mw) was performed by polystyrene equivalent.

### (ii) Acid Value of Resin

Approximately 1 g of resin was precisely weighed and taken into a conical flask with a stopper, and 50 mL of toluene/ethanol (volume ratio: toluene/ethanol=2/1) mixed solution was added to dissolve the resin. To this, a phenolphthalein test solution was added as an indicator and held for 30 seconds. Thereafter, titration was performed with 0.1 mol/L alcoholic potassium hydroxide solution until the solution exhibited a pale pink color. The acid value was obtained by the following formula. The acid value was taken as the numerical value of the resin in a dry state.

$$Acid value ( mg KOH / g ) = ( a \times F \times 56.1 \times 0.1 ) / S$$

S: Collection amount of sample×(solid content of sample/100) (g)
a: Titration amount of 0.1 mol/L alcoholic potassium hydroxide solution (mL)
F: Titer of 0.1 mol/L alcoholic potassium hydroxide solution
   (iii) Tg of Resin

In accordance with JIS K7198, Tg was measured using a dynamic viscoelasticity measuring device DVA-200 (manufactured by IT Keisoku Seigyo Co., Ltd.). A PET film with a thickness of 50 μm coated with a silicone release agent was prepared as a release substrate. The resin was applied on this release substrate using a doctor blade to a thickness of 20 μm, dried at 100° C. for 2 minutes, and the obtained sheet was cut to 0.5 cm×3 cm. The sample with the release film peeled off was used for measurement. In the measurement, the deformation mode was tension, and the temperature at which the main dispersion peak of loss tangent (tan δ) appeared was taken as Tg, measured at a strain of 0.08%, a frequency of 10 Hz, and a temperature rise rate of 10° C./min.

### (iv) Preparation of Half-Cut Wafer for Test

A silicon bare wafer (size 100 mmφ, thickness 525 μm) was prepared, and a half-cut wafer for test was obtained by forming half-cut grooves with a width of 200 μm and a depth of 200 μm at 4000 μm lattice interval, with use of a dicing device (DISCO DAD323).

### (b) Production of Resin Composition, Electromagnetic Wave Shielding Sheet, and Laminate

### [Production of Resin Composition of Example 1]

100 parts of solid content of high molecular weight resin P3, 40 parts of epoxy group-containing compound E3, 1 part of curable compound C1, 180 parts of filler F2, and 35 parts of filler F4 were charged into a container, and a mixed solvent of toluene:isopropyl alcohol (mass ratio 2:1) was added so that the non-volatile content (solid content) concentration became 35%, followed by stirring with a disper for 10 minutes to obtain a resin composition. The solid content equivalent amounts of all components are shown in Table 1.

### Examples 2 to 20 and Comparative Examples 1 to 6

Resin compositions were produced in the same manner as Example 1 except for the changes shown in Tables 1 to 3.

The materials used in the examples and the abbreviations in Tables 1 to 3 are shown below.

### <Binder Component>

### [High Molecular Weight Resin (P)]

P1: polycarbonate resin, Mw=180,000, acid value 10 [mgKOH/g], Tg 10° C. (manufactured by TOYO CHEM)
P2: polycarbonate resin, Mw=260,000, acid value 10 [mgKOH/g], Tg 10° C. (manufactured by TOYO CHEM)
P3: polycarbonate resin, Mw=120,000, acid value 10 [mgKOH/g], Tg 10° C. (manufactured by TOYO CHEM)
P4: polycarbonate resin, Mw=110,000, acid value 12 [mgKOH/g], Tg −10° C. (manufactured by TOYO CHEM)
P5: polycarbonate resin, Mw=50,000, acid value 18 [mgKOH/g], Tg 20° C. (manufactured by TOYO CHEM)
P6: polycarbonate resin, Mw=110,000, acid value 3 [mgKOH/g], Tg 10° C. (manufactured by TOYO CHEM)
P7: polycarbonate resin, Mw=110,000, acid value 28 [mgKOH/g], Tg 10° C. (manufactured by TOYO CHEM)
P8: urethane resin, Mw=130,000, acid value 10 [mgKOH/g], Tg 40° C. (manufactured by TOYO CHEM)
P9: urethane resin, Mw=130,000, acid value 10 [mgKOH/g], Tg 60° C. (manufactured by TOYO CHEM)
P10: ester resin, Mw=140,000, acid value 10 [mgKOH/g], Tg −15° C. (manufactured by TOYO CHEM)

### [Other Resins]

R1: acrylic resin, Mw=8,000, acid value 15 [mgKOH/g](manufactured by TOYO CHEM)

### <Curable Compound (C)>

C1: “Chemitite PZ-33” (aziridine compound, Mw=425) manufactured by Nippon Shokubai [Epoxy Group-containing Compound (E)]
E1: “jER604” (diaminodiphenylmethane type epoxy resin, Mw=350, epoxy equivalent=120 g/eq) manufactured by Mitsubishi Chemical
E2: “jER1032H” (trisphenol methane type epoxy resin, Mw=500, epoxy equivalent=170 g/eq) manufactured by Mitsubishi Chemical
E3: “jER834” (bisphenol A type epoxy resin, Mw=470, epoxy equivalent=250 g/eq) manufactured by Mitsubishi Chemical
E4: “EPICLON1050” (bisphenol A type epoxy resin, Mw=900, epoxy equivalent=475 g/eq) manufactured by DIC
E5: “EPICLON3050” (bisphenol A type epoxy resin, Mw=1800, epoxy equivalent=800 g/eq) manufactured by DIC

### [Other Curable Compounds]

R2: “jER1010” (bisphenol A type epoxy resin, Mw=5500, epoxy equivalent=4000 g/eq) manufactured by Mitsubishi Chemical

### <Conductive Filler (F)>

F1: scale-shaped silver filler (D₅₀=1.0 μm to 3.0 μm, average specific surface area 1.1 m²/g) manufactured by Tokusen Kogyo
F2: scale-shaped silver filler (D₅₀=4.0 μm to 7.0 μm, average specific surface area 1.5 m²/g) manufactured by Fukuda Metal Foil & Powder
F3: scale-shaped silver filler (D₅₀=5.0 μm to 10.0 μm, average specific surface area 0.3 m²/g) manufactured by Fukuda Metal Foil & Powder
F4: dendritic silver-coated copper filler (D₅₀=7.4 μm, average specific surface area 0.7 m²/g) manufactured by Mitsui Mining & Smelting
F5: dendritic silver-coated copper filler (scale-shaped silver filler D₅₀=10.4 μm, average specific surface area 0.6 m²/g) manufactured by DOWA

TABLE 1

| | | | | Example | | | | | | | | | | | |
|---|---|---|---|---|---|---|---|---|---|---|---|---|---|---|---|
| | | | | 1 | 2 | 3 | 4 | 5 | 6 | 7 | 8 | 9 | 10 | 11 | 12 |
| Binder | High molecular weight | | P1 | | | | | | | | | | | 100 | |
| Component | resin (P) | | P2 | | | | | | | | | | 100 | | |
| | | | P3 | 100 | 100 | 100 | 100 | 100 | 100 | 100 | 100 | 100 | | | |
| | | | P4 | | | | | | | | | | | | 100 |
| | | | P5 | | | | | | | | | | | | |
| | | | P6 | | | | | | | | | | | | |
| | | | P7 | | | | | | | | | | | | |
| | | | P8 | | | | | | | | | | | | |
| | | | P9 | | | | | | | | | | | | |
| | | | P10 | | | | | | | | | | | | |
| | Other resins | | R1 | | | | | | | | | | | | |
| | Curable | Epoxy group- | E1 | | | | | | | | | | | | |
| | compound | containing | E2 | | 20 | 35 | | 20 | 35 | | 20 | 35 | 20 | 20 | 20 |
| | (C) | compound | E3 | 40 | 20 | 10 | 40 | 20 | 10 | 40 | 20 | 10 | 20 | 20 | 20 |
| | | (E) | E4 | | | | | | | | | | | | |
| | | | E5 | | | | | | | | | | | | |
| | | Curable | C1 | 1 | 1 | 1 | 1 | 1 | 1 | 1 | 1 | 1 | 1 | 1 | 1 |
| | | compound | | | | | | | | | | | | | |

| | |
|---|---|
| Other curable compounds | R2 |

| Filler (F) | F1 | | | | | | | | | | | | |
|---|---|---|---|---|---|---|---|---|---|---|---|---|---|
| | F2 | 180 | 180 | 180 | 260 | 260 | 260 | 500 | 500 | 500 | 260 | 260 | 260 |
| | F3 | | | | | | | | | | | | |
| | F4 | 35 | 35 | 35 | 60 | 60 | 60 | 100 | 100 | 100 | 60 | 60 | 60 |
| | F5 | | | | | | | | | | | | |

| | | | | | | | | | | | | |
|---|---|---|---|---|---|---|---|---|---|---|---|---|
| Content [α] (parts) of filler (F) per | 215 | 215 | 215 | 320 | 320 | 320 | 600 | 600 | 600 | 320 | 320 | 320 |
| 100 parts of binder component | | | | | | | | | | | | |
| Content ratio (%) of filler (F) in sheet | 60% | 60% | 60% | 69% | 69% | 69% | 81% | 81% | 80% | 69% | 69% | 69% |
| [α] × average specific surface area (m²) | 313 | 313 | 313 | 458 | 458 | 458 | 870 | 870 | 870 | 458 | 458 | 458 |
| of filler (F) | | | | | | | | | | | | |
| Elongation rate (%) at 100° C. of | 1060 | 1030 | 1010 | 880 | 800 | 760 | 170 | 140 | 110 | 950 | 900 | 850 |
| electromagnetic wave shielding sheet | | | | | | | | | | | | |
| Young's modulus (MPa) at 100° C. | 150 | 210 | 280 | 320 | 350 | 430 | 570 | 780 | 830 | 610 | 400 | 300 |
| after curing of electromagnetic wave | | | | | | | | | | | | |
| shielding sheet | | | | | | | | | | | | |

TABLE 2

| | | | | Example | | | | | | | | | | | |
|---|---|---|---|---|---|---|---|---|---|---|---|---|---|---|---|
| | | | | 13 | 14 | 15 | 16 | 17 | 18 | 19 | 20 | 21 | 22 | 23 | 24 |
| Binder | High molecular weight | | P1 | | | | | | | | | | | | |
| Component | resin (P) | | P2 | | | | | | | | | | | | |
| | | | P3 | | | | | | | 100 | 100 | 100 | 100 | 100 | 100 |
| | | | P4 | | | | | | | | | | | | |
| | | | P5 | 100 | | | | | | | | | | | |
| | | | P6 | | | | 100 | | | | | | | | |
| | | | P7 | | | | | 100 | | | | | | | |
| | | | P8 | | 100 | | | | | | | | | | |
| | | | P9 | | | 100 | | | | | | | | | |
| | | | P10 | | | | | | 100 | | | | | | |
| | Other resins | | R1 | | | | | | | | | | | | |
| | Curable | Epoxy group- | E1 | | | | | | | | | 40 | | | |
| | compound | containing | E2 | 20 | 20 | 20 | 20 | 20 | 20 | | | | 20 | 20 | 20 |
| | (C) | compound | E3 | 20 | 20 | 20 | 20 | 20 | 20 | | | | 20 | 20 | 20 |
| | | (E) | E4 | | | | | | | | 40 | | | | |
| | | | E5 | | | | | | | 40 | | | | | |
| | | Curable | C1 | 1 | 1 | 1 | 1 | 1 | 1 | 1 | 1 | 1 | 1 | 1 | 1 |
| | | compound | | | | | | | | | | | | | |

| | |
|---|---|
| Other curable compounds | R2 |

| Filler (F) | F1 | | | | | | | | | | | | |
|---|---|---|---|---|---|---|---|---|---|---|---|---|---|
| | F2 | 260 | 260 | 260 | 260 | 260 | 260 | 260 | 260 | 260 | 260 | 200 | |
| | F3 | | | | | | | | | | | | |
| | F4 | 60 | 60 | 60 | 60 | 60 | 60 | 60 | 60 | 60 | | | |
| | F5 | | | | | | | | | | 60 | 100 | 300 |

| | | | | | | | | | | | | |
|---|---|---|---|---|---|---|---|---|---|---|---|---|
| Content [α] (parts) of filler (F) per | 320 | 320 | 320 | 320 | 320 | 320 | 320 | 320 | 320 | 320 | 300 | 300 |
| 100 parts of binder component | | | | | | | | | | | | |
| Content ratio (%) of filler (F) in sheet | 69% | 69% | 69% | 69% | 69% | 69% | 69% | 69% | 69% | 69% | 68% | 68% |
| [α] × average specific surface area (m²) | 458 | 458 | 458 | 458 | 458 | 458 | 458 | 458 | 458 | 452 | 380 | 180 |
| of filler (F) | | | | | | | | | | | | |
| Elongation rate (%) at 100° C. of | 300 | 420 | 230 | 140 | 430 | 770 | 780 | 750 | 600 | 810 | 720 | 510 |
| electromagnetic wave shielding sheet | | | | | | | | | | | | |
| Young's modulus (MPa) at 100° C. | 170 | 500 | 850 | 180 | 750 | 320 | 390 | 430 | 520 | 360 | 360 | 360 |
| after curing of electromagnetic wave | | | | | | | | | | | | |
| shielding sheet | | | | | | | | | | | | |

TABLE 3

| | | | | Example | | | | Comparative Example | | | | | |
|---|---|---|---|---|---|---|---|---|---|---|---|---|---|
| | | | | 25 | 26 | 27 | 28 | 1 | 2 | 3 | 4 | 5 | 6 |
| Binder | High molecular weight | | P1 | | | | | | | | | | |
| Component | resin (P) | | P2 | | | | | | | | | | |
| | | | P3 | 100 | 100 | 100 | 100 | | 100 | 100 | 100 | 100 | 100 |
| | | | P4 | | | | | | | | | | |
| | | | P5 | | | | | | | | | | |
| | | | P6 | | | | | | | | | | |
| | | | P7 | | | | | | | | | | |
| | | | P8 | | | | | | | | | | |
| | | | P9 | | | | | | | | | | |
| | | | P10 | | | | | | | | | | |
| | Other resins | | R1 | | | | | 100 | | | | | |
| | Curable | Epoxy group- | E1 | | | | | | | | | | |
| | compound | containing | E2 | 20 | 20 | 20 | 20 | | | | | | |
| | (C) | compound | E3 | 20 | 20 | 20 | 20 | | 100 | 5 | | | |
| | | (E) | E4 | | | | | | | | | | |
| | | | E5 | | | | | 30 | | | | 30 | 30 |
| | | Curable | C1 | 1 | 1 | 1 | 1 | 1 | 1 | 1 | 1 | 1 | 1 |
| | | compound | | | | | | | | | | | |

| | | |
|---|---|---|
| Other curable compounds | R2 | 50 |

| Filler (F) | F1 | 300 | | | | | | | | | |
|---|---|---|---|---|---|---|---|---|---|---|---|
| | F2 | | | 110 | 90 | 300 | 400 | 200 | 400 | | 690 |
| | F3 | | 300 | | | | | | | | |
| | F4 | 15 | 15 | 30 | 27 | 15 | | | | | |
| | F5 | | | | | | | | | 45 | |

| | | | | | | | | | | |
|---|---|---|---|---|---|---|---|---|---|---|
| Content [α] (parts) of filler (F) per | 315 | 315 | 140 | 117 | 315 | 400 | 200 | 400 | 45 | 690 |
| 100 parts of binder component | | | | | | | | | | |
| Content ratio (%) of filler (F) in sheet | 69% | 69% | 50% | 45% | 71% | 67% | 65% | 73% | 26% | 84% |
| [α] × average specific surface area (m²) | 341 | 101 | 197 | 163 | 491 | 640 | 320 | 640 | 27 | 1104 |
| of filler (F) | | | | | | | | | | |
| Elongation rate (%) at 100° C. of | 540 | 450 | 1200 | 1400 | 25 | 70 | 1020 | 90 | 1550 | 40 |
| electromagnetic wave shielding sheet | | | | | | | | | | |
| Young's modulus (MPa) at 100° C. | 360 | 420 | 120 | 100 | 50 | 1300 | 80 | 1200 | 20 | 930 |
| after curing of electromagnetic wave | | | | | | | | | | |
| shielding sheet | | | | | | | | | | |

### (Manufacturing of Electromagnetic Wave Shielding Sheet)

A PET film with a thickness of 50 μm coated with a silicone release agent on the surface was prepared as a release substrate. On this release substrate, the resin composition of each example and comparative example was applied using a doctor blade so that the dry thickness became 40 jam. Then, by drying at 100° C. for 2 minutes, an electromagnetic wave shielding sheet with the release substrate according to each example and comparative example was obtained.

### (Preparation of Laminate)

Thereafter, a release cushion member was prepared, and the sheet surface of the electromagnetic wave shielding sheet with the release substrate of each example and comparative example and a cushion sheet (CR1040 manufactured by Mitsui Tohcello) were laminated using a thermal laminator at a temperature of 70° C., a pressure of 0.1 MPa, and a speed of 1 m/min to obtain a laminate according to each example and comparative example.

### (c) Properties of Electromagnetic Wave Shielding Sheet and Others

For the above examples and comparative examples, the elongation rate and Young's modulus were determined by the following methods. The results are shown in Tables 1 to 3.

### <Elongation Rate at 100° C.>

The electromagnetic wave shielding sheet obtained by peeling the release substrate and the cushion sheet of each example was placed still for 24 hours at 23° C. and 50% relative humidity in a constant temperature and humidity chamber, and then placed still for 1 minute in a chamber maintained at 100° C. Thereafter, under a temperature of 100° C., the electromagnetic wave shielding sheet was subjected to a stress-strain curve measurement using a tensile testing machine “EZ Tester” (manufactured by Shimadzu Corporation) under conditions of a tensile speed of 50 mm/min and a gauge length of 25 mm, and the elongation rate at the breaking point was measured as the elongation rate at 100° C.

### <Young's Modulus of Cured Sheet at 100° C.>

The electromagnetic wave shielding sheet obtained by peeling the release substrate and the cushion sheet was heated at 180° C. for 2 hours to obtain a cured sheet. After being placed still at 23° C. and 50% relative humidity in a constant temperature and humidity chamber, the cured sheet was placed still for 1 minute in a chamber maintained at 100° C. Thereafter, under a temperature of 100° C., the cured sheet was subjected to a stress-strain curve measurement using a tensile testing machine “EZ Tester” (manufactured by Shimadzu Corporation) under conditions of a tensile speed of 50 mm/min and a gauge length of 25 mm. Linear regression (slope) in the region where strain (elongation) was 0.1% to 0.3% was measured as the Young's modulus at 100° C.

### (d) Evaluation of Electromagnetic Wave Shielding Sheet and Others

For the above examples and comparative examples, adhesive force, coating properties, warpage, and appearance were evaluated by the following methods. The results are shown in Table 4.

<Adhesive Force to Silicon Bare Wafer after PCT Test>

A silicon bare wafer (size 100 mmφ, thickness 525 μm) was prepared, and the above laminate was cut to 50 mm×50 mm, the release substrate was peeled off, and the electromagnetic wave shielding sheet layer was placed on the bare wafer. Thereafter, hot pressing was performed from above the cushion sheet of the laminate on the bare wafer under conditions of a temperature of 120° C. and a pressure of 5 MPa for 3 minutes. After hot pressing, cooling was performed, the cushion layer was peeled off, and heating was performed at 180° C. for 2 hours to obtain a test piece in which a shield cover layer was formed. Next, a pressure cooker test (conditions: 130° C., 85% RH, 0.12 MPa, 96 hours) was performed on this test substrate. Thereafter, 100 cross-hatch squares at intervals of 1 mm were formed on the shield cover layer of the test substrate using a cross-cut guide in accordance with JIS K5400. Subsequently, an adhesive tape was strongly pressed against the cross-hatch portion, and the end of the tape was peeled off at once at an angle of 45°, and the state of the cross-hatch was evaluated according to the following criteria.
+++: Peeling rate was less than 5%.
++: The coating film partially peeled along the cut lines, and the peeling rate was 5% or more and less than 10%.
+: The coating film partially peeled along the cut lines, and the peeling rate was 10% or more and less than 15%.
NG: The coating film partially or entirely peeled along the cut lines, and the peeling rate was 15% or more. Not practical.

### <Resistance Value Between Half-Cut Grooves>

The laminate was cut to 100 mmφ, the release substrate was peeled off, and the electromagnetic wave shielding sheet layer was placed on a test half-cut wafer. Thereafter, hot pressing was performed from above the cushion sheet of the laminate on the test half-cut wafer under conditions of a temperature of 120° C. and a pressure of 5 MPa for 3 minutes. After hot pressing, cooling was performed, subsequently the cushion layer was peeled off, and heating was performed at 180° C. for 2 hours to obtain a shielded wafer. Then, using RM3544 manufactured by HIOKI and a pin-type lead probe, the probe was applied to the central portion of the upper surface of the shield cover layer in two adjacent semiconductor element formation regions, and the resistance value between half-cut grooves was evaluated. The evaluation criteria are as follows.
+++: Resistance value was less than 50 mΩ. Very good result.
++: Resistance value was 50 mΩ or more and less than 150 mΩ. Good result.
+: Resistance value was 150 mΩ or more and less than 300 mΩ. No practical problem.
NG: Resistance value was 300 mΩ or more. Not practical.

### <Warpage Height>

The shielded wafer obtained above was placed on a horizontal surface, the maximum value of the distance between the placed surface and the wafer edge was measured, and the warpage height was evaluated. The evaluation criteria are as follows.
+++: Warpage height was less than 1 mm. Very good result.
++: Warpage height was 1 mm or more and less than 2 mm. Good result.
+: Warpage height was 2 mm or more and less than 5 mm. No practical problem.
NG: Warpage height was 5 mm or more. Not practical.

### <Appearance of Diced Product>

From the upper surface of the shielded wafer obtained above, full cutting was performed with a width of 50 μm to pass through the central portion of the half-cut grooves using a dicing device (DISCO DAD323), and 100 diced products were obtained. Then, the appearance was observed visually, and the number of diced products having peeling or chipping of the electromagnetic wave shielding sheet was counted. The evaluation criteria are as follows.
+++: Number of diced products having peeling or chipping of the electromagnetic wave shielding sheet was less than 5. Very good.
++: Number of diced products having peeling or chipping of the electromagnetic wave shielding sheet was 5 or more and less than 10. Good.
+: Number of diced products having peeling or chipping of the electromagnetic wave shielding sheet was 10 or more and less than 20. No practical problem.
NG: Number of diced products having peeling or chipping of the electromagnetic wave shielding sheet was 20 or more. Not practical.

TABLE 4

| | | Peeling | Resistance | | Appearance |
|---|---|---|---|---|---|
| | | rate after | value between | Warpage | of diced |
| | | PCT test | half-cut grooves | height | product |
| Example | 1 | +++ | ++ | +++ | +++ |
| | 2 | +++ | ++ | +++ | +++ |
| | 3 | +++ | ++ | +++ | +++ |
| | 4 | +++ | +++ | +++ | +++ |
| | 5 | +++ | +++ | +++ | +++ |
| | 6 | +++ | +++ | +++ | +++ |
| | 7 | ++ | ++ | +++ | +++ |
| | 8 | ++ | ++ | +++ | ++ |
| | 9 | + | + | ++ | + |
| | 10 | ++ | ++ | +++ | ++ |
| | 11 | +++ | +++ | +++ | +++ |
| | 12 | ++ | +++ | +++ | +++ |
| | 13 | + | ++ | ++ | ++ |
| | 14 | +++ | ++ | +++ | ++ |
| | 15 | ++ | + | ++ | + |
| | 16 | + | + | +++ | + |
| | 17 | +++ | + | + | + |
| | 18 | ++ | +++ | +++ | ++ |
| | 19 | + | +++ | +++ | ++ |
| | 20 | ++ | +++ | +++ | +++ |
| | 21 | +++ | ++ | ++ | +++ |
| | 22 | +++ | +++ | +++ | +++ |
| | 23 | +++ | ++ | +++ | +++ |
| | 24 | +++ | + | +++ | + |
| | 25 | +++ | ++ | +++ | +++ |
| | 26 | +++ | ++ | +++ | +++ |
| | 27 | +++ | ++ | +++ | +++ |
| | 28 | +++ | + | +++ | +++ |
| Compar- | 1 | NG | ++ | NG | NG |
| ative | 2 | NG | NG | + | NG |
| Example | 3 | NG | ++ | +++ | +++ |
| | 4 | + | NG | +++ | + |
| | 5 | +++ | NG | ++ | +++ |
| | 6 | NG | NG | +++ | NG |

The electromagnetic wave shielding sheet in which the Young's modulus at 100° C. in the cured sheet exceeds 1000 MPa was confirmed to have a high resistance value between half-cut grooves, as shown in Comparative Examples 2 and 4, and had issues with the coating properties of recesses. In the case of the Young's modulus at 100° C. in the cured sheet being less than 100 MPa, as shown in Comparative Examples 1 and 3, it was confirmed that the peelability after PCT test deteriorated, and there were issues with adhesion to the adherend. In the case of the Young's modulus at 100° C. in the cured sheet being less than 1000 MPa, the peelability after PCT test became good according to a high elongation rate at 100° C., but as shown in Comparative Example 5, it was confirmed that the resistance value between half-cut grooves was high, and there were issues with coating properties of recesses. In contrast, the electromagnetic wave shielding sheet in which the elongation rate at 100° C. was 100% to 1500% and the Young's modulus at 100° C. of the cured sheet after treating the electromagnetic wave shielding sheet at 180° C. for 2 hours became 100 MPa to 1000 MPa, as shown in Examples 1 to 28, was confirmed to have excellent adhesion, coating properties, warpage, and appearance.

What is claimed is:

1. An electromagnetic wave shielding sheet, for performing batch coating on at least one main surface of a semiconductor wafer before dicing which comprises half-cut grooves formed in a lattice pattern and element formation regions partitioned by the half-cut grooves and arranged in a matrix pattern,
the electromagnetic wave shielding sheet comprising at least a shielding film that comprises a binder component and a conductive filler (F),
wherein an elongation rate at 100° C. of the electromagnetic wave shielding sheet is 100% to 1500%, and
a Young's modulus at 100° C. of a cured sheet after treating the electromagnetic wave shielding sheet at 180° C. for 2 hours is 100 MPa to 1000 MPa.

2. The electromagnetic wave shielding sheet according to claim 1, wherein a peeling rate in an adhesion test after performing a pressure cooker test based on JIS K5600-5-6 on a shield cover layer derived from the electromagnetic wave shielding sheet after thermocompression bonding the electromagnetic wave shielding sheet to an entire main surface of a silicon bare wafer at 120° C. and 5 MPa for 3 minutes, followed by treatment at 180° C. for 2 hours, is less than 15%.

3. The electromagnetic wave shielding sheet according to claim 1, wherein the binder component comprises a curable compound (C) having a weight average molecular weight of 5,000 or less, and a high molecular weight resin (P) having a weight average molecular weight of 10,000 or more.

4. The electromagnetic wave shielding sheet according to claim 1, wherein a content ratio of the conductive filler (F) is 45% by mass to 85% by mass.

5. The electromagnetic wave shielding sheet according to claim 1, wherein a product of an average specific surface area [m²/g] of the conductive filler (F) and a content [g] of the conductive filler (F) relative to 100 parts by mass of the binder component is 50 to 1200 [m²].

6. The electromagnetic wave shielding sheet according to claim 1, wherein the curable compound (C) comprises an epoxy group-containing compound (E) having a weight average molecular weight of 5,000 or less,
an epoxy equivalent of the epoxy group-containing compound (E) is 110 g/eq to 1000 g/eq, and
10 parts by mass to 80 parts by mass of the epoxy group-containing compound (E) is included relative to 100 parts by mass of the high molecular weight resin (P).

7. The electromagnetic wave shielding sheet according to claim 1, wherein a shield cover layer derived from the electromagnetic wave shielding sheet is formed after thermocompression bonding the electromagnetic wave shielding sheet at 120° C. and 5 MPa for 3 minutes to an entire main surface of a 12-inch silicon bare wafer having half-cut grooves with a width of 200 μm and a depth of 200 μm formed in a lattice pattern at intervals of 4000 μm, and treating at 180° C. for 2 hours, and a resistance value between the shield cover layers coated on convex portions at adjacent positions via the half-cut grooves is 5 mΩ to 300 mΩ.

8. A shielded wafer, comprising a shield cover layer formed by the electromagnetic wave shielding sheet according to claim 1 on at least one main surface of a semiconductor wafer before dicing.

9. A semiconductor device, in which the shielded wafer according to claim 8 is diced in units of element formation regions.

10. A manufacturing method of a semiconductor device, comprising:
a step of forming half-cut grooves in a semiconductor wafer before dicing which comprises element formation regions formed in a matrix pattern along scribe lines;
a step of disposing the electromagnetic wave shielding sheet according to claim 1 above the semiconductor wafer;
a step of thermocompression bonding the electromagnetic wave shielding sheet to the semiconductor wafer;
a step of obtaining a shield cover layer by heating and curing the electromagnetic wave shielding sheet; and
a step of dicing in units of the element formation regions.
